(19) United States
(12) Patent Application Publication
(10) Pub. No.: US 2008/0309414 A1
(43) Pub. Date: Dec. 18, 2008

(54) VOLTAGE CONTROLLED OSCILLATOR AND PHASE LOCKED LOOP CIRCUIT INCORPORATING THE SAME

(75) Inventor: Akihide Sai, Kawasaki-shi (JP)

Correspondence Address: AMIN, TUROCY & CALVIN, LLP, 127 Public Square, 57th Floor, Key Tower, CLEVELAND, OH, 44114, US

(73) Assignee: Kabushiki Kaisha Toshiba, Tokyo (JP)

(21) Appl. No.: 12/051,103

(22) Filed: Mar. 19, 2008

(30) Foreign Application Priority Data
Jun. 13, 2007 (JP) 2007-156579

(51) Int. Cl. H03L 7/00; H03K 3/03

(52) U.S. Cl. 331/34; 331/57

(57) ABSTRACT

A voltage controlled oscillator includes a ring oscillator configured by connecting invertors, each of the invertors including a first and a second transistors, an operational amplifier to obtain an amplified signal, third transistors inserted between the first transistors and a first power supply, and is gate-controlled by the amplified signal, fourth transistors inserted between the second transistors and a second power supply, and is gate-controlled by the control signal, a inverter including a fifth and a sixth transistor, gate terminals and drain terminals of the fifth and sixth transistor being connected in common to a first input terminal of the operational amplifier, a seventh transistor inserted between the fifth transistor and the first power supply, and gate-controlled by the amplified signal, and an eighth transistor inserted between the sixth transistor and the second power supply, and gate-controlled by the control signal.

### CROSS-REFERENCE TO RELATED APPLICATIONS

This application is based upon and claims the benefit of priority from prior Japanese Patent Application No. 2007-156579, filed Jun. 13, 2007, the entire contents of which are incorporated herein by reference.

### BACKGROUND OF THE INVENTION

1. Field of the Invention

The present invention relates to a voltage controlled oscillator including a ring oscillator and a phase locked loop circuit incorporating such an oscillator.

2. Description of the Related Art

A voltage controlled oscillator that is used in a phase-locked loop (PLL) or the like outputs an oscillation signal of a frequency in correspondence with the voltage of an input control signal. At the time of up-conversion of the oscillation signal, however, phase noise caused in relation to thermal noise and 1/f noise (flicker noise) from the transistors of the voltage controlled oscillator accompany the oscillation signal. If the oscillation signal contains phase noise, the oscillation frequency tends to drift.

According to A. Hajimiri, S. Limotyrails, and T. H. Lee teach in “Jitter and Phase Noise in Ring Oscillators”, IEEE Journal of Solid-State Circuits, Vol. 34, No. 6, June 1999 that, as the slew rate of the rising edge of the oscillation signal from the voltage controlled oscillator is closer to the slew rate of the falling edge, or in other words, the more symmetrical the waveform of the oscillation signal, the lower the amount of accompanying flicker noise.

Voltage controlled oscillators include a ring oscillator that is formed of an odd number of inverters circularly connected to one another and which generates an oscillation signal from any of the inverters, are well known. A CMOS inverter of the following type is often adopted as an inverter of the ring oscillator. The gate terminal of a first PMOS transistor and the gate terminal of a first NMOS transistor are connected in common to the input terminal of the inverter, while the drain terminal of the first PMOS transistor and the drain terminal of the first NMOS transistor are connected in common to the output terminal of the inverter. In order to control the current flowing inside of the inverter, the source terminal of the first PMOS transistor is often connected to the drain terminal of a second PMOS transistor, while the source terminal of the first NMOS transistor is connected to the drain terminal of a second NMOS transistor. In such a structure, the source terminal of the second PMOS transistor is connected to a high-voltage source, while the source terminal of the second NMOS transistor is connected to a low-voltage source. Hereinafter, a circuit formed of such four transistors will be referred to as an inverter cell. The waveform of an oscillation signal generated by the ring oscillator is determined by the drain currents of the first PMOS transistor and the first NMOS transistor. That is, when the two drain currents are brought to be equal, the waveform of the oscillation signal becomes most symmetrical, and this reduces the phase noise.

JP-A H5-14136 (KOKAI) shows, in FIG. 4, a structure of arranging an operational amplifying circuit upstream of the ring oscillator. A control signal is applied to the gate terminal of an NMOS transistor N6, which serves as a tail current source of the operational amplifying circuit, thereby controlling the amount of tail current. The current mirror circuit copies a reference current that is determined on the basis of the tail current to the drain currents of the second PMOS transistors (P11, P13, P15) and the second NMOS transistors (N11, N13, N15) in the inverter cells. The drain current of the second PMOS transistors is equal to the drain currents of the first PMOS transistors (P12, P14, P16), and the drain currents of the second NMOS transistors is equal to the drain currents of the first NMOS transistors (N10, N12, N14). This means that the drain currents of the first PMOS transistors and of the first NMOS transistor are the same. JP-A H5-14136 (KOKAI) (in FIG. 4) therefore teaches a technique of temporarily converting the voltage of the control signal to a current and controlling the oscillation frequency by use of this current amount.

As described above, with the technique of JP-A H5-14136 (KOKAI) (in FIG. 4), the current mirror circuit copies the reference current from the operational amplifying circuit to the inverter cells. However, with the technique of the current mirror circuit copying the reference current to the inverter cells, MOS transistors (the second NMOS transistor and the second PMOS transistor) of each of the inverter cells needs to function as current sources. MOS transistors have three operating regions; a cutoff region, a linear region and a saturation region. Of the three regions, the MOS transistor can function as a current source only in the saturation region. For this reason, the range of the voltage of the control signal that is to improve the symmetry property of the oscillation signal waveform would be limited to the range in which the transistor serving as a current source can operate in the saturation region. In other words, because the control signal is applied to the gate terminal of the MOS transistor which serves as a tail current source of the operational amplifying circuit, the voltage of the control signal has to fall within the range in which the MOS transistor can operate in the saturation region.

On the contrary, it is known that the phase noise property of the ring oscillator is enhanced when the MOS transistors of the inverter cell operate in the linear region rather than the saturation region.

### BRIEF SUMMARY OF THE INVENTION

According to an aspect of the invention, there is provided a voltage controlled oscillator comprising: a ring oscillator configured by connecting an odd number of first MOS invertors into a shape of a ring to extract an oscillation signal having a frequency that is controlled by a voltage of a control signal, from any of the first MOS inverters, each of the first MOS invertors including first MOS transistor of one conductivity type and second MOS transistor of an opposite conductivity type; an operational amplifier which amplifies a difference between a voltage of a signal input to a first input terminal and a voltage of reference signal input to a second input terminal, to obtain an amplified signal; third MOS transistors of the one conductivity type, each of which is inserted between each of the first MOS transistors and a first power supply, and is gate-controlled by the amplified signal; fourth MOS transistors of the opposite conductivity type, each of which is inserted between each of the second MOS transistors and a second power supply, and is gate-controlled by the control signal; a second MOS inverter including a fifth MOS transistor of the one conductivity type and a sixth MOS transistor of the opposite conductivity type, a gate terminal and a drain terminal of the fifth MOS transistor being connected in common to the first input terminal and a gate terminal and a drain terminal of the six MOS transistor being connected in common to the first input terminal; a seventh MOS transistor of the one conductivity type inserted between the fifth MOS transistor and the first power supply, and gate-controlled by the amplified signal; and an eighth MOS transistor of the opposite conductivity type inserted between the sixth MOS transistor and the second power supply, and gate-controlled by the control signal.

According to another aspect of the invention, there is provided a voltage controlled oscillator comprising: a ring oscillator configured by connecting an odd number of first MOS invertors into a shape of a ring to extract an oscillation signal having a frequency that is controlled by a voltage of a control signal, from any of the first MOS inverters, each of the first MOS invertors including first MOS transistor of one conductivity type and second MOS transistor of an opposite conductivity type; an operational amplifier which amplifies a difference between a voltage of a signal input to a first input terminal and a voltage of reference signal input to a second input terminal, to obtain an amplified signal; a low-pass filter to remove high-frequency components from the amplified signal to obtain a filtered signal; third MOS transistors of the one conductivity type, each of which is inserted between each of the first MOS transistors and a first power supply, and is gate-controlled by the filtered signal; fourth MOS transistors of the opposite conductivity type, each of which is inserted between each of the second MOS transistors and a second power supply and, is gate-controlled by the control signal; a second MOS inverter including a fifth MOS transistor of the one conductivity type and a sixth MOS transistor of the opposite conductivity type, a gate terminal and a drain terminal of the fifth MOS transistor being connected in common to the first input terminal and a gate terminal and a drain terminal of the six MOS transistor being connected in common to the first input terminal; a seventh MOS transistor of the one conductivity type inserted between the fifth MOS transistor and the first power supply, and gate-controlled by the filtered signal; and an eighth MOS transistor of the opposite conductivity type inserted between the sixth MOS transistor and the second power supply, and gate-controlled by the control signal.

### BRIEF DESCRIPTION OF THE SEVERAL VIEWS OF THE DRAWING

FIG. 1 is a diagram showing a voltage controlled oscillator according to the first embodiment.

FIG. 2 is a diagram showing an example of an operational amplifier illustrated in FIG. 1.

FIG. 3A is a schematic diagram showing an example of the operation of an inverter cell illustrated in FIG. 1.

FIG. 3B is a schematic diagram showing another example of the operation of the inverter cell illustrated in FIG. 1.

FIG. 4 is a diagram showing a voltage controlled oscillator according to the second embodiment.

FIG. 5 is a diagram showing an example of an integrator illustrated in FIG. 4.

FIG. 6 is a block diagram showing a phase locked loop circuit according to the third embodiment.

FIG. 7 is a block diagram showing a phase locked loop circuit according to the fourth embodiment.

### DETAILED DESCRIPTION OF THE INVENTION

The exemplary embodiments of the present invention will be explained with reference to the drawings.

### First Embodiment

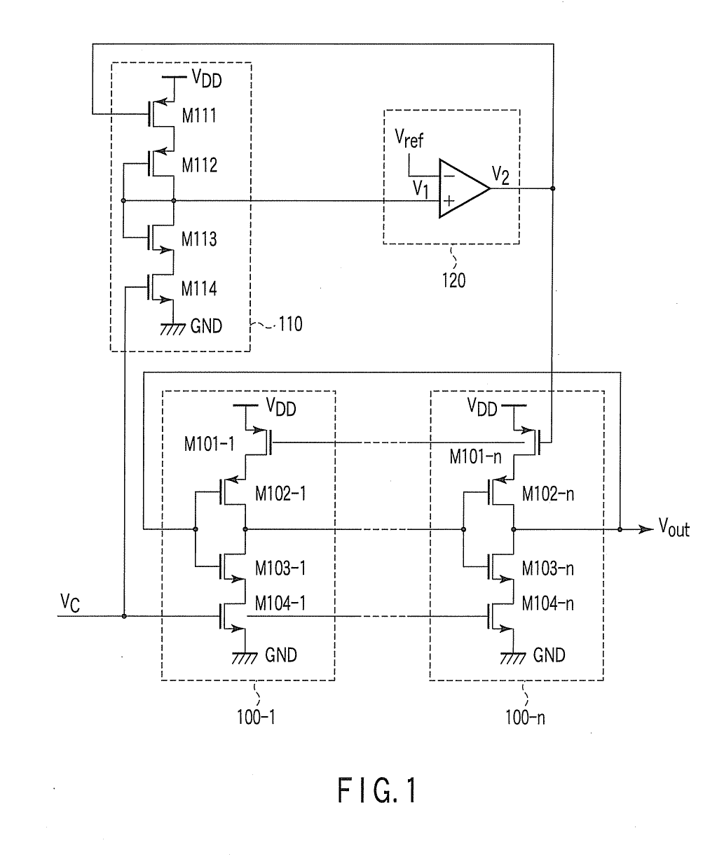

As illustrated in FIG. 1, a voltage controlled oscillator according to the first embodiment of the present invention comprises a number n (n is an odd number) of inverter cells 100-1 to 100-n, a dummy inverter cell 110 and an operational amplifier 120.

The inverter cells 100-1 to 100-n have the same circuitry, and are circularly connected to one another to form a ring oscillator. As an example of an inverter cell, the structure of the inverter cell 100-1 will be explained below.

The gate terminals of PMOS transistor M102-1 and NMOS transistor M103-1 are connected in common to the input terminal of the inverter cell 100-1. The drain terminals of the PMOS transistor M102-1 and NMOS transistor M103-1 are connected in common to the output terminal of the inverter cell 100-1. In other words, a CMOS inverter is formed by the PMOS transistor M102-1 and the NMOS transistor M103-1 together. The source terminal of a PMOS transistor M101-1 is connected to a power source VDD (high voltage source), while the source terminal of an NMOS transistor M104-1 is connected to a ground source GND (low voltage source). The source terminal of the PMOS transistor M102-1 is connected to the drain terminal of the PMOS transistor M101-1, and the source terminal of the NMOS transistor M103-1 is connected to the drain terminal of the NMOS transistor M104-1. An output signal (amplified signal) V2 output by the operational amplifier 120 is applied to the gate terminal of the PMOS transistor M101-1, and a control signal Vc is applied to the gate terminal of the NMOS transistor M104-1. The output terminal of this inverter cell is connected to the input terminal of the next inverter cell 100-2, and the rest of the inverter cells are connected to one another in the same manner. An oscillation signal Vout is output from the output terminal of the last inverter cell 100-n, which is connected to the input terminal of the inverter cell 100-1.

The dummy inverter cell 110 has the same circuitry as the inverter cells 100-1 to 100-n. The dummy inverter cell 110 is short-circuited between its input and output terminals. An output (input) signal V1 of the dummy inverter cell 110 is input to the first input terminal of the operational amplifier 120. In other words, the gate terminals and drain terminals of the PMOS transistor M112 and NMOS transistor M113 are all connected in common to the first input terminal of the operational amplifier 120.

The operational amplifier 120 is provided with the first input terminal and the second input terminal. The difference between the voltages of the signal input to the first input terminal and the signal input to the second input terminal are amplified by use of a gain A to output an amplified signal V2. As described above, the first input terminal of the operational amplifier 120 receives the output signal V1 from the dummy inverter cell 110. More specifically, the operational amplifier 120 has a negative feedback arrangement in which the output signal V2 is sent by way of the dummy inverter cell 110 back to the first input terminal. On the other hand, a reference signal Vref is input to the second input terminal of the operational amplifier 120. This means that the voltage of the amplified signal V2 output by the operational amplifier 120 is A*(V1−Vref). If the value of the gain A of the operational amplifier 120 is large enough, V1 converges to Vref. In the present embodiment, the connections are made in a manner that the first input terminal receives the output signal V1 from the dummy inverter cell 110 and the second input terminal receives the reference signal Vref, but these connections may be switched around.

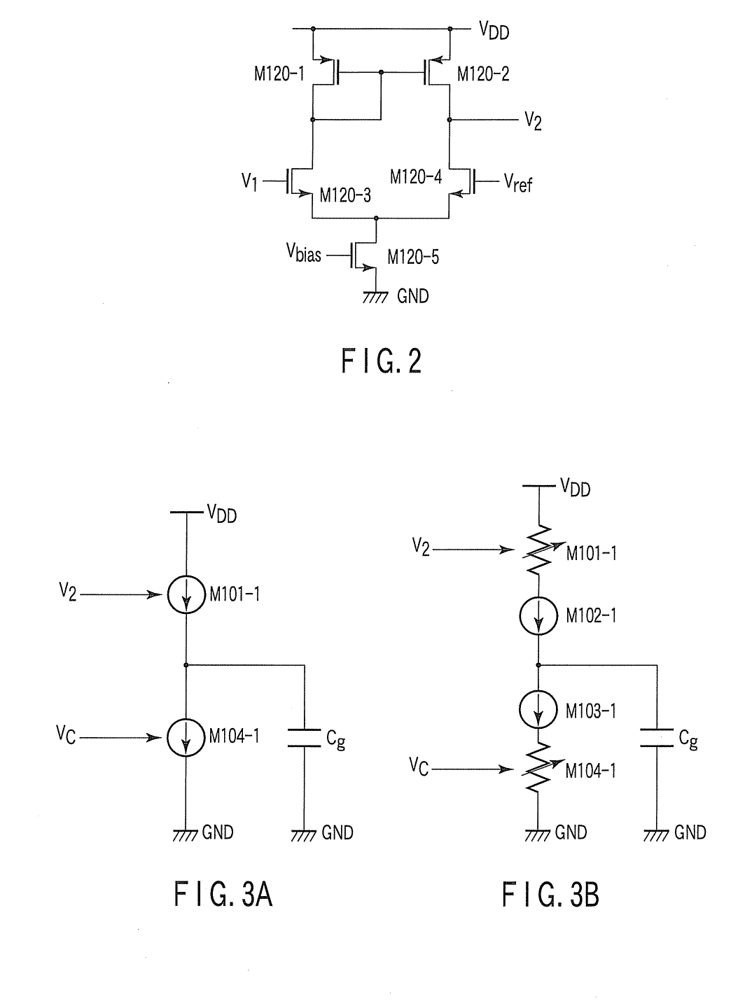

An example of the operational amplifier 120 will be explained with reference to FIG. 2. In the operational amplifier 120, the source terminals of a PMOS transistor M120-1 and a PMOS transistor M120-2 are individually connected to the power source VDD. The gate terminals of the PMOS transistors M120-1 and M120-2 are short-circuited and connected to the drain terminal of the PMOS transistor M120-1. The drain terminal of the PMOS transistor M120-2 is connected to the output terminal of the operational amplifier 120, from which the amplified signal V2 is output. The drain terminal of the PMOS transistor M120-1 is connected to the drain terminal of an NMOS transistor M120-3. The gate terminal of the NMOS transistor M120-3 is connected to the first input terminal of the operational amplifier 120, and receives the output signal V1 from the dummy inverter cell 110. The drain terminal of the PMOS transistor M120-2 is connected to the drain terminal of the NMOS transistor M120-4. The gate terminal of the NMOS transistor M120-4 is connected to the second input terminal of the operational amplifier 120, and receives the reference signal Vref. The source terminals of the NMOS transistors M120-3 and M120-4 are connected in common to the drain terminal of an NMOS transistor M120-5. The NMOS transistor M120-5 functions as a tail current source, and is driven by a bias voltage Vbias that is applied to its gate terminal. The source terminal of the NMOS transistor M120-5 is connected to the ground source GND, through which the tail current flows out.

The operation of the operational amplifier 120 shown in FIG. 2 will now be briefly explained. The PMOS transistor M120-1 and the PMOS transistor M120-2 are of the same kind (the sizes and the process parameters are same), and their voltages between the gates and sources are same. For this reason, the same amount of drain currents flow inside of the PMOS transistor M120-1 and the PMOS transistor M120-2. When the drain currents are Id, the drain current Id of the PMOS transistor M120-1 becomes the drain current of the NMOS transistor M120-3 as it is, and flows into the NMOS transistor M120-5. When the tail current carried into the NMOS transistor M120-5 is It, the drain current of the NMOS transistor M120-4 can be expressed as It-Id by applying Kirchoff's current law to the drain terminal of the NMOS transistor M120-5. Thus, out of the drain current Id of the PMOS transistor M120-2, It-Id is carried into the NMOS transistor M120-4, and the rest of the drain current, 2Id-It, flows out of the output terminal of the operational amplifier 120. If V1 sufficiently converges to Vref, the drain current of the NMOS transistor M120-3 becomes approximately equal to the drain current of the NMOS transistor M120-4, and thus Id=It/2 holds. As a result, the amount of current flowing into and out of the output terminal of the operational amplifier 120 becomes 0.

Next, the operation of the voltage controlled oscillator illustrated in FIG. 1 will be explained with reference to FIGS. 3A and 3B. In the following explanation, only the inverter cell 100-1 is dealt with, but other inverter cells, 100-2 to 100-n, operate in the same manner.

As shown in FIG. 3A, when the PMOS transistor M101-1 and the NMOS transistor M104-1 operate in the saturation region, the two MOS transistors M101-1 and M104-1 function as current sources and drive the gate capacitors Cg of MOS transistors (a PMOS transistor M102-2 and a NMOS transistor M103-2) which form the input terminal of the next inverter cell 100-2. More specifically, the gate capacitors Cg are charged with the drain current of the PMOS transistor M101-1 at the rising edge of the oscillation signal, while the gate capacitors Cg are discharged with the drain current of the NMOS transistor M104-1 at the falling edge. By making the drain currents of the PMOS transistor M101-1 and the NMOS transistor M104-1, both functioning as current sources, equal to each other, the symmetry property of the waveform of the oscillation signal can be improved. The drain current of the PMOS transistor M101-1 functioning as a current source is determined on the basis of the voltage between the power source VDD and the amplified signal V2. The drain current of the NMOS transistor M104-1 functioning as a current source is determined on the basis of the voltage between the control signal Vc and the ground source GND. Thus, the oscillation frequency can be controlled by the control signal Vc that controls the drain current of the NMOS transistor M104-1.

On the other hand, when the PMOS transistor M101-1 and the NMOS transistor M104-1 operate in the linear region as indicated in FIG. 3B, the two MOS transistors M101-1 and M104-1 function as variable resistors. The gate capacitors Cg of the MOS transistors (the NMOS transistor M102-2 and the PMOS transistor M103-2) that form the input terminal of the next inverter cell 100-2 are driven by the PMOS transistor M102-1 and the NMOS transistor M103-1 that function as current sources. More specifically, the gate capacitors Cg are charged with the drain current of the PMOS transistor M102-1 at the rising edge of the oscillation signal, while the gate capacitors Cg are discharged with the drain current of the NMOS transistor M103-1 at the falling edge. By making the drain currents of the PMOS transistor M102-1 and the NMOS transistor M103-1, both functioning as current sources, equal to each other, the symmetry property of the waveform of the oscillation signal can be improved. The drain current of the PMOS transistor M102-1 functioning as a current source is determined on the basis of its gate-source voltage. The gate-source voltage of the PMOS transistor M102-1 is equal to the difference voltage between the voltage dropped from the power source VDD by the PMOS transistor M101-1 and the voltage of the input signal of the inverter cell 100-1. The drain current of the NMOS transistor M103-1 functioning as a current source is determined on the basis of its gate-source voltage. The gate-source voltage of the NMOS transistor M103-1 is equal to the difference voltage between the voltage of the input signal of the inverter cell 100-1 and the voltage increasing from the GND by the NMOS transistor M104-1. With the control signal Vc controlling the resistance of the NMOS transistor M104-1 that functions as a variable resistor, the drain current of the NMOS transistor M103-1 can be indirectly controlled, and the oscillation frequency can also be controlled.

As mentioned above, the inverter cells 100-1 to 100-n have the same circuitry as the dummy inverter cell 110, and thus the amplified signal V2 is supplied thereto in such a manner that the input/output voltage of each of the inverter cells 100-1 to 100-n converges to the reference signal Vref. It should be noted, however, that the input/output voltages of the inverter cells 100-1 to 100-n vary. It is therefore very difficult to make the amount of current flowing in and out to the inverter cells equal at every operation point. Thus, it is preferable to use the mean value (arithmetic mean) of the voltages of the power source VDD and the ground source GND as the reference signal Vref. By use of the reference signal Vref determined in this manner, the oscillation signal becomes less prone to lose its waveform symmetry property even when the control signal Vc largely varies.

According to the present embodiment, as explained above, the input/output voltage of each of the inverter cells included in the ring oscillator is caused to converge to a reference signal based on negative feedback, thereby controlling the slew rates to be equal at the times of inputting and outputting. As a result, the waveform of the oscillation signal according to the present embodiment improves in its symmetry property, which reduces the phase noise. Furthermore, according to the present embodiment, when the MOS transistor M104 that receives the control signal operates in the linear region, the oscillation frequency is controlled by changing the resistance of the MOS transistor M104 functioning as a variable resistor. Hence, the phase noise can be reduced not only when the MOS transistors of the inverter cell operate in the saturation region but also when they operate in the linear region according to the present embodiment.

According to the embodiment, the control signal Vc is input into an NMOS transistor, while the amplified signal V2 is input into a PMOS transistor. However, the connections may be switched around.

### Second Embodiment

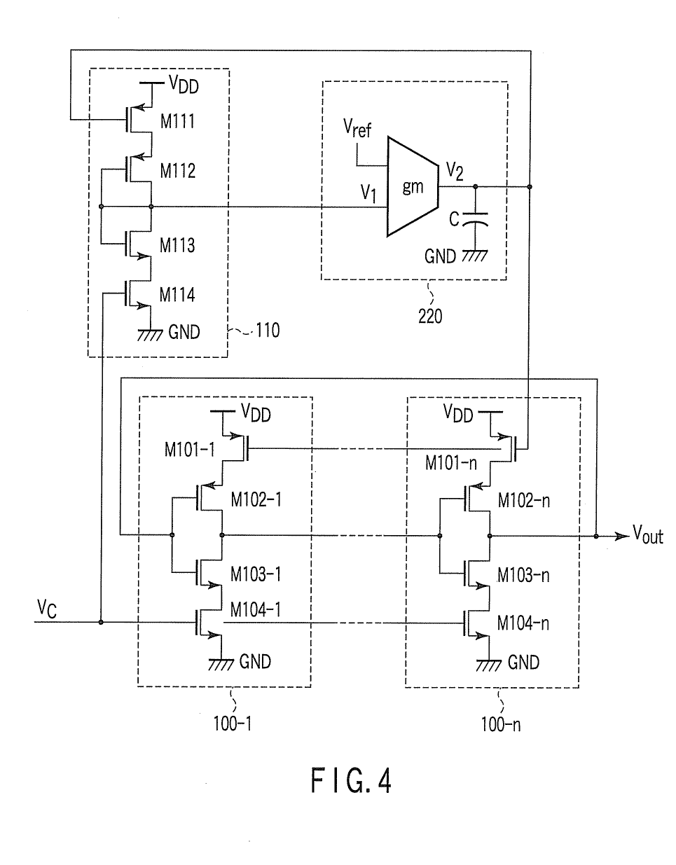

As illustrated in FIG. 4, a voltage controlled oscillator according to the second embodiment of the present invention comprises an integrator 220 in place of the operational amplifier 120 of the voltage controlled oscillator according to the first embodiment. In the following description, the components in FIG. 4 that are the same as those in FIG. 1 are given the same reference numerals, and the detailed explanation is omitted to focus on portions that are different from the structure of FIG. 1.

For the integrator 220, a gm-C integrator may be adopted from the aspects of low power consumption and low noise. The gm-C integrator is formed of an operational transconductance amplifier (OTA) and a capacitor. The OTA has a first input terminal and a second input terminal. The output signal V1 of the dummy inverter cell 110 is input to the first input terminal and the reference signal Vref is input to the second input terminal. The OTA is a voltage controlled current source that outputs a current corresponding to the difference between the voltages of two input signals multiplied by a transconductance gm. According to the present embodiment, the output current is gm*(V1−Vref), which indicates the difference between the voltages of the output signal V1 of the dummy inverter cell 110 and the reference signal Vref multiplied by transconductance gm. The output signal of the OTA is integrated by the capacitor C, and supplied to the inverter cells 100-1 to 100-n and the dummy inverter cell 110. In other words, the high frequency components of the output signal of the OTA are cut out.

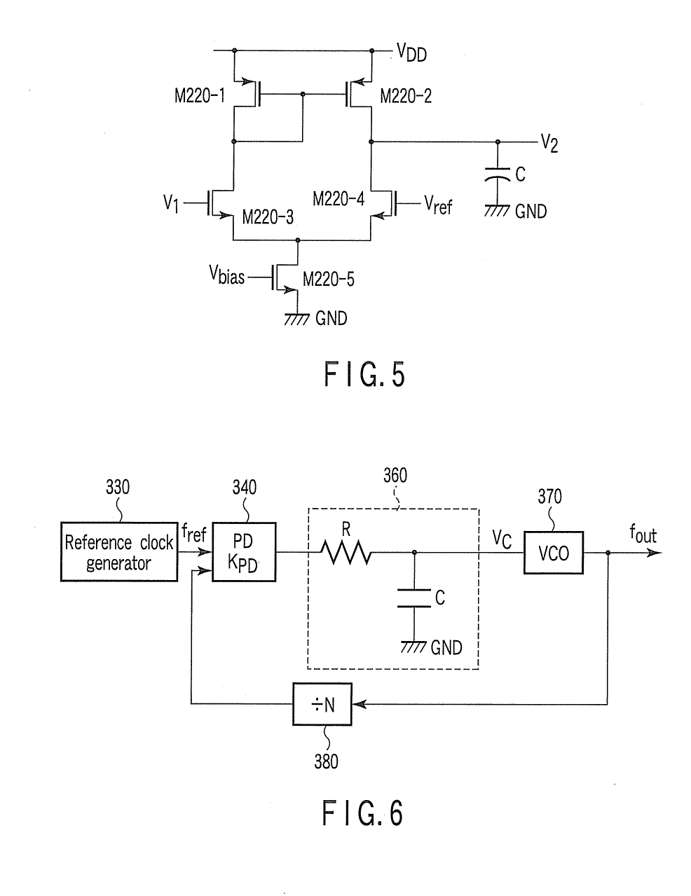

A specific example of the structure of the integrator 220 will be explained with reference FIG. 5. The OTA of the gm-C integrator 220 illustrated in FIG. 5 has the same structure as the operational amplifier 120 in FIG. 2. That is, MOS transistors M220-1 to M220-5 included in the OTA correspond to the MOS transistors M120-1 to M120-5 of the operational amplifier 120, respectively. In the gm-C integrator 220, the output signal of the OTA is integrated by the capacitor C. The capacitor C functions as a primary low-pass filter (LPF), cutting off the high frequency components of the output signal of the OTA. The cutoff frequency can be controlled by the capacitance of the capacitor C.

As explained above, the frequency band of the noise can be controlled by cutting off the high frequency components of the amplified signal, according to the present embodiment. Hence, the phase noise of the voltage controlled oscillator can be further reduced according to the present embodiment.

### Third Embodiment

As illustrated in FIG. 6, a phase locked loop circuit according to a third embodiment of the present invention comprises a reference clock generator 330, a phase detector 340, a loop filter 360, a voltage controlled oscillator 370 and a frequency-divider 380.

The reference clock generator 330 generates a reference clock signal of the reference frequency fref. The reference clock signal is input to the reference phase input terminal of the phase detector 340. The reference clock generator 330 may be externally arranged.

The phase detector 340 detects a difference between the phases of signals input to the reference phase input terminal and the oscillating phase input terminal. In other words, the phase detector 340 outputs a phase difference signal of a voltage corresponding to the difference between the phases of the reference clock signal input to the reference phase input terminal and a frequency-divided signal input to the oscillating phase input terminal multiplied by K_{PD}. This phase difference signal is input to the loop filter 360.

The phase difference signal of the phase detector 340 is input to the loop filter 360. The loop filter 360 may be formed of an LPF including resistors and capacitors (RC). The loop filter 360 removes alternate components from the phase difference signal. The filtered phase difference signal is then input to the voltage controlled oscillator 370 as the control signal Vc. In FIG. 6, a lag filter is adopted for the loop filter 360, but the loop filter 360 is not limited thereto.

The voltage controlled oscillator 370 is the voltage controlled oscillator according to the first or second embodiment, oscillating at a frequency corresponding to the input control signal Vc. The voltage controlled oscillator 370 which receives the control signal Vc outputs an oscillation signal of a frequency fout. The oscillation signal of the frequency fout is input to the frequency-divider 380.

The frequency-divider 380 divides the frequency of the oscillation signal of the voltage controlled oscillator 370 by a fixed or variable dividing ratio N, and outputs a frequency-divided signal of a frequency fout/N to the oscillating phase input terminal of the phase detector 340.

As discussed above, the phase locked loop circuit according to the present embodiment is constituted by use of the voltage controlled oscillator according to the first or second embodiment to obtain an oscillation signal of a frequency that corresponds to that of the reference clock signal multiplied by the dividing ratio. Thus, according to the present embodiment, an oscillation signal having a symmetrical waveform can be generated in correspondence with a control signal determined from a wide voltage range, and phase noise caused in relation to 1/f noise of the transistors can be suppressed.

### Fourth Embodiment

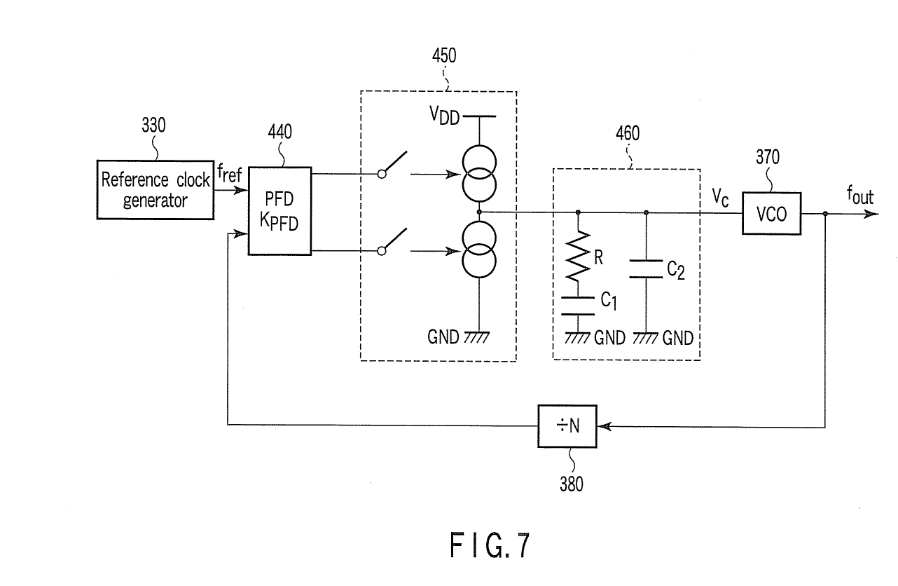

As illustrated in FIG. 7, a phase locked loop circuit according to the fourth embodiment of the present invention comprises a reference clock generator 330, a phase frequency detector 440, a charge pump 450, a loop filter 460, a voltage controlled oscillator 370, and a frequency-divider 380. In the following explanation, the components in FIG. 7 that are the same as those in FIG. 6 are given the same reference numerals, and the detailed description thereof is omitted. The explanation focuses on portions different from the structure of FIG. 6.

The reference clock generator 330 generates a reference clock signal of a reference frequency fref. The reference clock signal is input to the reference phase input terminal of the phase frequency detector 440. The reference clock generator 330 may be externally provided.

The phase frequency detector 440 detects a difference between the phases of signals input to the reference phase input terminal and the oscillating phase input terminal. In other words, when the phase frequency detector 440 detects that a deviation of the frequency-divided signal input to the oscillating phase input terminal from the reference clock signal input to the reference phase input terminal falls within one cycle, the phase frequency detector 440 outputs a phase difference signal of a voltage which corresponds to the phase difference multiplied by K_{PFD}, in a similar manner to the phase detector 340. On the other hand, when the phase frequency detector 440 detects that the deviation of the frequency-divided signal input to the oscillating phase input terminal from the reference clock signal input to the reference phase input terminal exceeds one cycle, the phase frequency detector 440 outputs a phase difference signal to reduce the difference between the frequencies. The phase frequency detector 440 may be simply a phase detector 340.

The phase difference signal output by the phase frequency detector 440 is input to the charge pump 450. The charge pump 450 is a booster circuit, and amplifies (boosts) the phase difference signal. The amplified (boosted) phase difference signal is input to the loop filter 460. The loop filter 460 is an LPF formed of, for example, resistors and capacitors (RC), and removes alternate components from the phase difference signal. The filtered phase difference signal is input to the voltage controlled oscillator 370 as a control signal Vc.

As discussed above, the phase locked loop circuit according to the present embodiment is configured to include the voltage controlled oscillator according to the first or second embodiment to obtain an oscillation signal of a frequency that corresponds to that of the reference clock signal multiplied by the dividing ratio. Hence, according to the present embodiment, an oscillation signal having a symmetrical waveform can be generated in correspondence with any control signal determined from a wide voltage range, and phase noise caused in relation to the 1/f noise of the transistors can be suppressed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A voltage controlled oscillator comprising:
a ring oscillator configured by connecting an odd number of first MOS invertors into a shape of a ring to extract an oscillation signal having a frequency that is controlled by a voltage of a control signal, from any of the first MOS inverters, each of the first MOS invertors including first MOS transistor of one conductivity type and second MOS transistor of an opposite conductivity type;
an operational amplifier which amplifies a difference between a voltage of a signal input to a first input terminal and a voltage of reference signal input to a second input terminal, to obtain an amplified signal;
third MOS transistors of the one conductivity type, each of which is inserted between each of the first MOS transistors and a first power supply, and is gate-controlled by the amplified signal;
fourth MOS transistors of the opposite conductivity type, each of which is inserted between each of the second MOS transistors and a second power supply, and is gate-controlled by the control signal;
a second MOS inverter including a fifth MOS transistor of the one conductivity type and a sixth MOS transistor of the opposite conductivity type, a gate terminal and a drain terminal of the fifth MOS transistor being connected in common to the first input terminal and a gate terminal and a drain terminal of the six MOS transistor being connected in common to the first input terminal;
a seventh MOS transistor of the one conductivity type inserted between the fifth MOS transistor and the first power supply, and gate-controlled by the amplified signal; and
an eighth MOS transistor of the opposite conductivity type inserted between the sixth MOS transistor and the second power supply, and gate-controlled by the control signal.

2. The oscillator according to claim 1, wherein
the voltage of the reference signal is an arithmetic mean of a voltage of the first power supply and a voltage of the second power supply.

3. A voltage controlled oscillator comprising:
a ring oscillator configured by connecting an odd number of first MOS invertors into a shape of a ring to extract an oscillation signal having a frequency that is controlled by a voltage of a control signal, from any of the first MOS inverters, each of the first MOS invertors including first MOS transistor of one conductivity type and second MOS transistor of an opposite conductivity type;
an operational amplifier which amplifies a difference between a voltage of a signal input to a first input terminal and a voltage of reference signal input to a second input terminal, to obtain an amplified signal;
a low-pass filter to remove high-frequency components from the amplified signal to obtain a filtered signal;
third MOS transistors of the one conductivity type, each of which is inserted between each of the first MOS transistors and a first power supply, and is gate-controlled by the filtered signal;
fourth MOS transistors of the opposite conductivity type, each of which is inserted between each of the second MOS transistors and a second power supply and, is gate-controlled by the control signal;
a second MOS inverter including a fifth MOS transistor of the one conductivity type and a sixth MOS transistor of the opposite conductivity type, a gate terminal and a drain terminal of the fifth MOS transistor being connected in common to the first input terminal and a gate terminal and a drain terminal of the six MOS transistor being connected in common to the first input terminal;
a seventh MOS transistor of the one conductivity type inserted between the fifth MOS transistor and the first power supply, and gate-controlled by the filtered signal; and
an eighth MOS transistor of the opposite conductivity type inserted between the sixth MOS transistor and the second power supply, and gate-controlled by the control signal.

4. The oscillator according to claim 3, wherein
the voltage of the reference signal is an arithmetic mean of a voltage of the first power supply and a voltage of the second power supply.

5. A phase locked loop circuit comprising:
a ring oscillator configured by connecting an odd number of first MOS invertors into a shape of a ring to extract an oscillation signal having a frequency that is controlled by a voltage of a control signal, from any of the first MOS inverters, each of the first MOS invertors including first MOS transistor of one conductivity type and second MOS transistor of an opposite conductivity type;
an operational amplifier which amplifies a difference between a voltage of a signal input to a first input terminal and a voltage of reference signal input to a second input terminal, to obtain an amplified signal;
third MOS transistors of the one conductivity type, each of which is inserted between each of the first MOS transistors and a first power supply, and is gate-controlled by the amplified signal;
fourth MOS transistors of the opposite conductivity type, each of which is inserted between each of the second MOS transistors and a second power supply, and is gate-controlled by the control signal;
a second MOS inverter including a fifth MOS transistor of the one conductivity type and a sixth MOS transistor of the opposite conductivity type, a gate terminal and a drain terminal of the fifth MOS transistor being connected in common to the first input terminal and a gate terminal and a drain terminal of the six MOS transistor being connected in common to the first input terminal;
a seventh MOS transistor of the one conductivity type inserted between the fifth MOS transistor and the first power supply, and gate-controlled by the amplified signal;
an eighth MOS transistor of the opposite conductivity type inserted between the sixth MOS transistor and the second power supply, and gate-controlled by the control signal;
a frequency-divider to divide the frequency of the oscillation signal to obtain a frequency-divided signal;
a phase detector to detect a phase difference of the frequency-divided signal and a reference clock signal, and obtain a phase difference signal; and
a loop filter to remove AC components from the phase difference signal to obtain the control signal.

6. The circuit according to claim 5, further comprising:
a charge pump which is inserted between the phase detector and the loop filter, to boost a voltage of the phase difference signal.

7. The circuit according to claim 5, wherein
the voltage of the reference signal is an arithmetic mean of a voltage of the first power supply and a voltage of the second power supply.

8. The circuit according to claim 5, further comprising:
a clock generator which generates the reference clock signal.

9. A phase locked loop circuit comprising:
a ring oscillator configured by connecting an odd number of first MOS invertors into a shape of a ring to extract an oscillation signal having a frequency that is controlled by a voltage of a control signal, from any of the first MOS inverters, each of the first MOS invertors including first MOS transistor of one conductivity type and second MOS transistor of an opposite conductivity type;
an operational amplifier which amplifies a difference between a voltage of a signal input to a first input terminal and a voltage of reference signal input to a second input terminal, to obtain an amplified signal;
a low-pass filter to remove high-frequency components from the amplified signal to obtain a filtered signal;
third MOS transistors of the one conductivity type, each of which is inserted between each of the first MOS transistors and a first power supply, and is gate-controlled by the filtered signal;
fourth MOS transistors of the opposite conductivity type, each of which is inserted between each of the second MOS transistors and a second power supply and, is gate-controlled by the control signal;
a second MOS inverter including a fifth MOS transistor of the one conductivity type and a sixth MOS transistor of the opposite conductivity type, a gate terminal and a drain terminal of the fifth MOS transistor being connected in common to the first input terminal and a gate terminal and a drain terminal of the six MOS transistor being connected in common to the first input terminal;
a seventh MOS transistor of the one conductivity type inserted between the fifth MOS transistor and the first power supply, and gate-controlled by the filtered signal;
an eighth MOS transistor of the opposite conductivity type inserted between the sixth MOS transistor and the second power supply, and gate-controlled by the control signal;
a frequency-divider to divide the frequency of the oscillation signal to obtain a frequency-divided signal;
a phase detector to detect a phase difference of a phase of the frequency-divided signal and a phase of a reference clock signal, and obtain a phase difference signal; and
a loop filter to remove alternate components from the phase difference signal to obtain the control signal.

10. The circuit according to claim 9, further comprising:
a charge pump which is inserted between the phase detector and the loop filter, to boost a voltage of the phase difference signal.

11. The circuit according to claim 9, wherein
the voltage of the reference signal is an arithmetic mean of a voltage of the first power supply and a voltage of the second power supply.

12. The circuit according to claim 9, further comprising:
a clock generator which generates the reference clock signal.
